(19) United States
(12) Patent Application Publication
(10) Pub. No.: US 2025/0215568 A1
(43) Pub. Date: Jul. 3, 2025

(54) Substrate Processing Apparatus, Gas Supply Assembly, Substrate Processing Method, Method of Manufacturing Semiconductor Device and Non-transitory Computer-Readable Recording Medium

(71) Applicant: Kokusai Electric Corporation, Tokyo (JP)

(72) Inventors: Yusaku OKAJIMA, Toyama (JP); Takatomo YAMAGUCHI, Toyama (JP); Yuji TAKEBAYASHI, Toyama (JP); Hiroki HATTA, Toyama (JP)

(21) Appl. No.: 19/085,129

(22) Filed: Mar. 20, 2025

Related U.S. Application Data
(63) Continuation of application No. PCT/JP2023/011683, filed on Mar. 24, 2023.

(30) Foreign Application Priority Data
Sep. 20, 2022 (JP) 2022-149628

(51) Int. Cl. C23C 16/455; C23C 16/44

(52) U.S. Cl. CPC C23C 16/45561; C23C 16/4408; C23C 16/4412

(57) ABSTRACT

For reducing a risk of oxygen permeation, there is provided a technique that includes: a first gas supplier supplying a first gas; a first structure allowing the first gas to pass therethrough from the first gas supplier; a second structure allowing the first gas to pass therethrough from the first structure; a third structure allowing the first gas to pass therethrough from the second structure; a process chamber to which the first gas is supplied from the third structure; a first seal between the first structure and the second structure; a second seal between the second structure and the third structure; a second gas supplier supplying a second gas; a first gas path arranged along the second seal to allow the second gas to pass therethrough; and a second gas path arranged along the first seal to allow the second gas to pass therethrough.

### CROSS REFERENCE TO RELATED APPLICATIONS

This application is a bypass continuation application of PCT International Application No. PCT/JP2023/011683, filed on Mar. 24, 2023, which claims priority under 35 U.S.C. § 119 (a)-(d) to Japanese Patent Application No. 2022-149628, filed on Sep. 20, 2022, the entire contents of which are hereby incorporated by reference.

### TECHNICAL FIELD

The present disclosure relates to a substrate processing apparatus, a gas supply assembly, a substrate processing method, a method of manufacturing a semiconductor device and a non-transitory computer-readable recording medium.

### BACKGROUND

According to some related arts, as one of substrate processing apparatuses used in a manufacturing process of a semiconductor device, for example, a substrate processing apparatus capable of collectively processing (that is, batch-processing) a plurality of substrates may be used.

In a semiconductor manufacturing apparatus (that is, the substrate processing apparatus) capable of processing a substrate such as a semiconductor wafer in a vacuum vessel (also referred to as a “reaction tube”) which is in a reduced pressure state, there is a high risk of oxygen (O₂) permeating through a connection portion of an opening of the vacuum vessel.

### SUMMARY

According to the present disclosure, there is provided a technique capable of reducing a risk of oxygen (O₂) permeation.

According to an embodiment of the present disclosure, there is provided a technique that includes: a first gas supplier configured to supply a first gas; a first structure configured to allow the first gas to pass therethrough from the first gas supplier; a second structure configured to allow the first gas to pass therethrough from the first structure; a third structure configured to allow the first gas to pass therethrough from the second structure; a process chamber to which the first gas is supplied from the third structure; a first seal provided between the first structure and the second structure; a second seal provided between the second structure and the third structure; a second gas supplier configured to supply a second gas; a first gas path arranged along the second seal and configured to allow the second gas to pass therethrough; and a second gas path arranged along the first seal and configured to allow the second gas to pass therethrough.

### BRIEF DESCRIPTION OF THE DRAWINGS

FIG. 1 is a diagram schematically illustrating an exemplary configuration of a substrate processing apparatus according to one or more embodiments of the present disclosure.

FIG. 2 is a diagram schematically illustrating a horizontal cross-section of the substrate processing apparatus according to the embodiments of the present disclosure, taken along a line α-α′ shown in FIG. 1.

FIG. 3A is a diagram schematically illustrating a gas supply system including a gas supply pipe 251 according to the embodiments of the present disclosure, and FIG. 3B is a diagram schematically illustrating a gas supply system including a gas supply pipe 261 according to the embodiments of the present disclosure.

FIG. 4 is a block diagram schematically illustrating a controller and related components of the substrate processing apparatus according to the embodiments of the present disclosure.

FIG. 5 is a flow chart schematically illustrating a process flow of a substrate processing according to the embodiments of the present disclosure.

FIG. 6 is a diagram schematically illustrating a cross-section of a gas supply structure according to the embodiments of the present disclosure.

FIG. 7 is a diagram schematically illustrating a perspective view of front and back surfaces of a first structure and a second structure according to the embodiments of the present disclosure.

FIG. 8 is a diagram schematically illustrating a partial perspective view of the front and back surfaces of the first structure and the second structure according to the embodiments of the present disclosure.

FIG. 9 is a diagram schematically illustrating a first purge gas path and a second purge gas path according to the embodiments of the present disclosure.

FIG. 10 is a diagram schematically illustrating a purge gas supply system according to the embodiments of the present disclosure.

FIG. 11 is a diagram schematically illustrating a permeation amount of oxygen (O₂) (that is, an amount of oxygen (O₂) permeated) according to the embodiments of the present disclosure.

### DETAILED DESCRIPTION

Hereinafter, one or more embodiments (also simply referred to as “embodiments”) according to the technique of the present disclosure will be described with reference to the drawings. The drawings used in the following descriptions are all schematic. For example, a relationship between dimensions of each component and a ratio of each component shown in the drawing may not always match the actual ones. Further, even between the drawings, the relationship between the dimensions of each component and the ratio of each component may not always match.

### (1) Configuration of Substrate Processing Apparatus

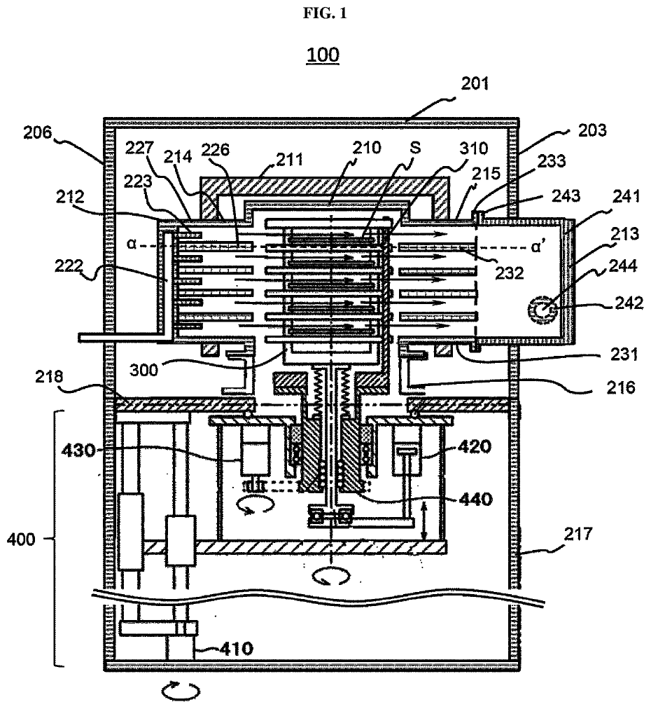

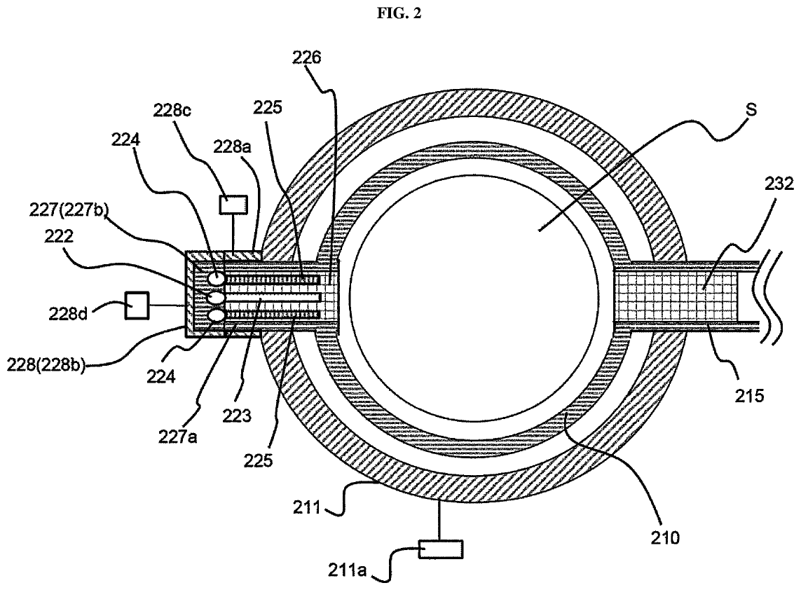

Hereinafter, an outline of a substrate processing apparatus 100 according to the embodiments of the present disclosure will be described with reference to FIGS. 1 to 4. FIG. 1 is a diagram schematically illustrating a vertical cross-section of the substrate processing apparatus 100, and FIG. 2 is a diagram schematically illustrating a horizontal cross-section of the substrate processing apparatus 100, taken along a line α-α′ in FIG. 1. In FIG. 2, for convenience of the following descriptions, a nozzle 223 and a nozzle 225 are additionally illustrated.

Subsequently, the substrate processing apparatus 100 will be described in detail. The substrate processing apparatus 100 includes a housing 201, and the housing 201 includes a reaction tube storage chamber 206 and a transfer chamber 217. The reaction tube storage chamber 206 is arranged on the transfer chamber 217.

In the reaction tube storage chamber 206, a reaction tube 210 of a cylindrical shape extending in a vertical direction (up-down direction), a heater 211 serving as a heating structure (furnace body) installed on an outer periphery of the reaction tube 210, a gas supply structure 212 serving as a part of a gas supply assembly and a gas exhaust structure 213 serving as a part of a gas exhaust assembly are provided. In the present specification, the reaction tube 210 may also be referred to as a “process chamber”, and a space (inner space) of the reaction tube 210 may also be referred to as a “process space”. The reaction tube 210 is configured to be capable of storing a substrate support 300 described later.

The heater 211 is provided with a resistance heating heater on an inner surface thereof facing the reaction tube 210, and a heat insulator (not shown) is provided so as to surround the heater 211 and the resistance heating heater. Thereby, an external portion of the heater 211 (that is, a portion that does not face the reaction tube 210) is configured to be less affected by a heat. A heater controller 211a is electrically connected to the resistance heating heater of the heater 211. By controlling the heater controller 211a, it is possible to control a turn-on/turn-off (also simply referred to as an “ON/OFF”) of the heater 211 and a heating temperature of the heater 211. The heater 211 is capable of heating a gas described later to a temperature at which the gas is capable of being thermally decomposed. In addition, the heater 211 may also be referred to as a “process chamber heater” or a “first heater”.

In the reaction tube storage chamber 206, the reaction tube 210, an upstream side gas guide 214 and a downstream side gas guide 215 are provided. The gas supply assembly may further include the upstream side gas guide 214, and the gas exhaust assembly may further include the downstream side gas guide 215.

The gas supply structure 212 is provided at an upstream side of the reaction tube 210 in a gas flow direction, and the gas is supplied into the reaction tube 210 through the gas supply structure 212. The gas exhaust structure 213 is provided at a downstream side of the reaction tube 210 in the gas flow direction, and the gas in the reaction tube 210 is discharged (exhausted) through the gas exhaust structure 213.

The upstream side gas guide 214 configured to adjust a flow of the gas supplied through the gas supply structure 212 is provided between the reaction tube 210 and the gas supply structure 212. That is, the gas supply structure 212 is provided adjacent to the upstream side gas guide 214. In addition, the downstream side gas guide 215 configured to adjust the flow of the gas discharged from the reaction tube 210 is provided between the reaction tube 210 and the gas exhaust structure 213. A lower end of the reaction tube 210 is supported by a manifold 216.

The reaction tube 210, the upstream side gas guide 214 and the downstream side gas guide 215 are implemented as a continuous structure. For example, each of the reaction tube 210, the upstream side gas guide 214 and the downstream side gas guide 215 is made of a material such as quartz and silicon carbide (SiC). In addition, each of the reaction tube 210, the upstream side gas guide 214 and the downstream side gas guide 215 is constituted by a heat permeable structure capable of transmitting the heat radiated from the heater 211. The heat of the heater 211 is capable of heating a plurality of substrates including a substrate S and the gas. Hereafter, the plurality of substrates including the substrate S may also be simply referred to as “substrates S.”

A housing constituting the gas supply structure 212 is made of a metal, and a housing 227 (which is a part of the upstream side gas guide 214) is made of a material such as quartz. The gas supply structure 212 and the housing 227 are separable from each other. When fixing the gas supply structure 212 and the housing 227, the gas supply structure 212 and the housing 227 are fixed via an O-ring such as an O-ring (which is a second seal) 22901 and an O-ring (which is a fourth seal) 22902 described later. The housing 227 is connected to a connection structure (not shown) provided at a side wall of the reaction tube 210.

The housing 227 extends in a direction away from the reaction tube 210 when viewed from the reaction tube 210, and is connected to the gas supply structure 212 described later. The heater 211 and the housing 227 are provided adjacent to each other at a portion 227b between the reaction tube 210 and the gas supply structure 212. The portion 227b may also be referred to as an “adjacent portion 227b”.

The gas supply structure 212 is provided inner than the adjacent portion 227b when viewed from the reaction tube 210. The gas supply structure 212 includes: a distributor 224 capable of communicating with a gas supply pipe 261 described later; and a distributor 222 capable of communicating with a gas supply pipe 251 described later. A plurality of nozzles including the nozzle 223 are provided on a downstream side of the distributor 222, and a plurality of nozzles including the nozzle 225 are provided on a downstream side of the distributor 224. Hereinafter, the plurality of nozzles including the nozzle 223 may also be simply referred to as “nozzles 223”, and the plurality of nozzles including the nozzle 225 may also be simply referred to as “nozzles 225”. Each of the nozzles 223 and each of the nozzles 225 are arranged in the vertical direction. In FIG. 1, the distributor 222 and the nozzle 223 are illustrated.

As described later, the distributor 222 may also be referred to as a “source gas distributor” because the distributor 222 is configured to be capable of distributing a source gas. The nozzle 223 may also be referred to as a “source gas supply nozzle” because the source gas is supplied through the nozzle 223.

In addition, the distributor 224 may also be referred to as a “reactive gas distributor” because the distributor 224 is configured to be capable of distributing a reactive gas. The nozzle 225 may also be referred to as a “reactive gas supply nozzle” because the reactive gas is supplied through the nozzle 225.

As described later, gases of different types are supplied through the gas supply pipe 251 and the gas supply pipe 261, respectively. As shown in FIG. 2, the nozzle 223 and the nozzle 225 are arranged next to each other in a horizontal direction. According to the present embodiments, for example, the nozzle 223 is arranged at a center of the housing 227 in the horizontal direction, and the nozzles 225 are arranged on both sides of the nozzle 223. The nozzles 225 arranged on both sides of the nozzle 223 may also be referred to as nozzles 225a and 225b, respectively.

A partition plate 226 is a continuous structure without a hole. A plurality of partition plates including a partition plate 226 are provided at positions corresponding to the substrates S, respectively. Hereafter, the plurality of partition plates including the partition plate 226 may also be simply referred to as “partition plates 226”. The nozzle 223 and the nozzles 225 are arranged between adjacent partition plates 226, between an uppermost partition plate (among the partition plates 226) and the housing 227 or between a lowermost partition plate (among the partition plates 226) and the housing 227. Hereinafter, the uppermost partition plate among the partition plates 226 and the lowermost partition plate among the partition plates 226 may also be referred to as an “uppermost partition plate 226” and a “lowermost partition plate 226”, respectively. That is, the nozzle 223 and the nozzles 225 are provided at least for each of the partition plates 226. With such a configuration, it is possible to perform a process using a first element-containing gas and a second element-containing gas in between adjacent partition plates 226, in between the uppermost partition plate 226 and the housing 227 or in between the lowermost partition plate 226 and the housing 227. Therefore, it is possible to uniformize a state of the process between the substrates S.

In addition, it is preferable that distances between the partition plates 226 and their corresponding nozzles 223 arranged thereabove are set to be equal to one another. That is, distances between the nozzles 223 and their corresponding partition plates 226 arranged therebelow or distances between the nozzles 223 and the housing 227 are set to be equal to one another. With such a configuration, a distance from a front end (tip) of each of the nozzles 223 to its corresponding one of the partition plates 226 can be set to be constant. Thereby, it is possible to uniformize a degree of decomposition of the gas on each of the substrates S.

The gas ejected through the nozzle 223 or the nozzle 225 is supplied to a surface (front surface) of the substrate S after the flow of the gas is adjusted by the partition plate 226. Since the partition plate 226 extends in the horizontal direction and is a continuous structure without a hole, a mainstream of the gas is restrained from moving in the vertical direction and is thereby moved in the horizontal direction. Therefore, it is possible to uniformize a pressure loss of the gas reaching each of the substrates S over the vertical direction.

According to the present embodiments, a diameter of each of ejection holes (not shown) provided in the distributor 222 is configured to be smaller than a distance between adjacent partition plates 226, a distance between the housing 227 and the uppermost partition plate 226 or a distance between the housing 227 and the lowermost partition plate 226.

The downstream side gas guide 215 is configured such that a ceiling thereof is provided above an uppermost substrate among the substrates S supported by the substrate support 300, and a bottom thereof is provided below a lowermost substrate among the substrates S supported by the substrate support 300.

The downstream side gas guide 215 includes a housing 231 and a plurality of partition plates including a partition plate 232. Hereinafter, the plurality of partition plates including the partition plate 232 may also be simply referred to as “partition plates 232”. A portion of the partition plate 232, which faces the substrate S, extends in the horizontal direction such that a horizontal extending length of the partition plate 232 is at least greater than a diameter of the substrate S. The “horizontal direction” in which the partition plate 232 extends may refer to a direction toward a side wall of the housing 231. In addition, the partition plates 232 are arranged in a multistage manner in the vertical direction in the housing 231. The partition plate 232 is fixed to the side wall of the housing 231 such that it is possible to prevent the gas from flowing into an adjacent region below or above the partition plate 232. By preventing the gas from flowing beyond the partition plate 232, it is possible to reliably form the flow of the gas described later. A flange 233 is provided on a portion of the housing 231 that comes into contact with the gas exhaust structure 213.

The partition plate 232 is a continuous structure without a hole. The partition plates 232 are provided at positions corresponding to the substrates S and corresponding to the partition plates 226, respectively. It is preferable that the partition plate 226 and the partition plate 232 corresponding to the partition plate 226 are provided at the same height. In addition, when processing the substrate S, it is preferable that the substrate S, the partition plate 226 corresponding to the substrate S and the partition plate 232 corresponding to the partition plate 226 are provided at the same height. With such a structure, the flow of the gas (supplied through each nozzle) passes over the partition plate 226, the substrate S and the partition plate 232 is formed by the gas supplied through each nozzle, as shown by each arrow in FIG. 1. As described above, the partition plate 232 extends in the horizontal direction and is a continuous structure without a hole. With such a configuration, it is possible to uniformize the pressure loss of the gas ejected (or discharged) through each of the substrates S. Therefore, the flow of the gas passing over each of the substrates S is formed in the horizontal direction toward the gas exhaust structure 213 while suppressing a flow of the gas in the vertical direction.

By providing the partition plates 226 and the partition plates 232, it is possible to uniformize the pressure loss in the vertical direction at both an upstream and a downstream of each of the substrates S. As a result, it is possible to reliably form the flow of the gas in the horizontal direction while the flow of the gas in the vertical direction is suppressed across the partition plate 226, the substrate S and the partition plate 232.

The gas exhaust structure 213 is provided at a downstream side of the downstream side gas guide 215. The gas exhaust structure 213 is constituted mainly by a housing 241 and a gas exhaust pipe connection structure 242. A flange 243 is provided on a portion of the housing 241 adjacent to the downstream side gas guide 215.

The gas exhaust structure 213 communicates with a space of the downstream side gas guide 215. The housing 231 and the housing 241 are continuous in height. That is, a height of a ceiling of the housing 231 is configured to be the same as that of a ceiling of the housing 241, and a height of a bottom of the housing 231 is configured to be the same as that of a bottom of the housing 241.

The gas that has passed through the downstream side gas guide 215 is exhausted through an exhaust hole 244. When the gas is exhausted through the exhaust hole 244, since the gas exhaust structure 213 is not provided with a structure similar to the partition plate described above, the flow of the gas whose direction includes a vertical component is formed toward the exhaust hole 244.

The transfer chamber 217 is installed in a lower portion of the reaction tube 210 via the manifold 216. In the transfer chamber 217, the substrate S may be transferred to (or placed on) the substrate support 300 (hereinafter, may also be simply referred to as a “boat 300”) by a vacuum transfer robot (not shown), or the substrate S may be transferred out of the substrate support 300 by the vacuum transfer robot.

In the transfer chamber 217, the substrate support 300, a partition plate support 310 (which are collectively referred to as a “substrate retainer”) and a vertical driving structure 400 can be stored. The vertical driving structure 400 constitutes a first driver configured to drive the substrate support 300 and the partition plate support 310 in the vertical direction and in a rotational direction. FIG. 1 schematically illustrates a state in which the substrate support 300 is elevated by the vertical driving structure 400 and stored in the reaction tube 210.

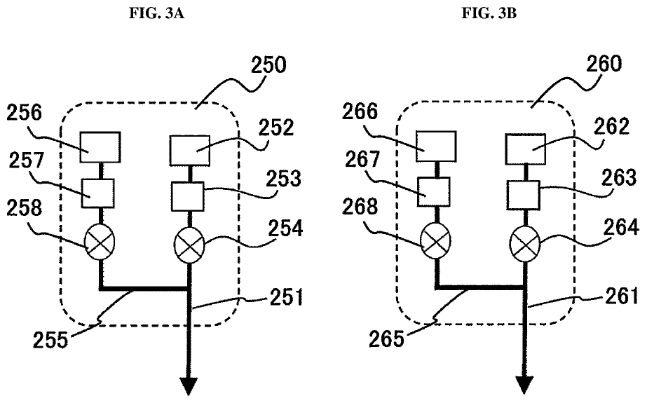

Subsequently, gas supply systems will be described in detail with reference to FIGS. 3A and 3B.

As shown in FIG. 3A, a first element-containing gas supply source 252, a mass flow controller (MFC) 253 serving as a flow rate controller (a flow rate control structure) and a valve 254 serving as an opening/closing valve are sequentially installed at the gas supply pipe 251 in this order from an upstream side to a downstream side of the gas supply pipe 251.

The first element-containing gas supply source 252 is a source of the first element-containing gas containing a first element. The first element-containing gas serves as the source gas, which is one of process gases.

A first clement-containing gas supply system 250 is constituted mainly by the gas supply pipe 251, the MFC 253 and the valve 254. The gas supply pipe 251 is connected to an introduction pipe (not shown) of the distributor 222.

A gas supply pipe 255 is connected to a downstream side of the valve 254 of the gas supply pipe 251. An inert gas supply source 256, an MFC 257 and a valve 258 serving as an opening/closing valve are sequentially installed at the gas supply pipe 255 in this order from an upstream side to a downstream side of the gas supply pipe 255. An inert gas is supplied from the inert gas supply source 256.

A first inert gas supply system is constituted mainly by the gas supply pipe 255, the MFC 257 and the valve 258. The inert gas supplied from the inert gas supply source 256 acts as a purge gas for purging the gas remaining in the reaction tube 210 when a substrate processing described later is performed. The first element-containing gas supply system 250 may further include the first inert gas supply system.

As shown in FIG. 3B, a second clement-containing gas supply source 262, a mass flow controller (MFC) 263 serving as a flow rate controller (a flow rate control structure) and a valve 264 serving as an opening/closing valve are sequentially installed at the gas supply pipe 261 in this order from an upstream side to a downstream side of the gas supply pipe 261. The gas supply pipe 261 is connected to an introduction pipe (not shown) of the distributor 224.

The second element-containing gas supply source 262 is a source of the second element-containing gas (that is, a gas containing a second element). The second element-containing gas is one of the process gases. In addition, the second element-containing gas may act as the reactive gas or a modification gas. Hereinafter, the first element-containing gas and the second element-containing gas may also be collectively or individually referred to as a “process gas.” In addition, the process gas may also be referred to as a “first gas.” That is, the term “first gas” may refer to the first element-containing gas, may refer to the second element-containing gas, or may refer to both of the first element-containing gas and the second element-containing gas.

A second element-containing gas supply system 260 is constituted mainly by the gas supply pipe 261, the MFC 263 and the valve 264.

A gas supply pipe 265 is connected to a downstream side of the valve 264 of the gas supply pipe 261. An inert gas supply source 266, an MFC 267 and a valve 268 serving as an opening/closing valve are sequentially installed at the gas supply pipe 265 in this order from an upstream side to a downstream side of the gas supply pipe 265. The inert gas is supplied from the inert gas supply source 266.

A second inert gas supply system is constituted mainly by the gas supply pipe 265, the MFC 267 and the valve 268. The inert gas supplied from the inert gas supply source 266 acts as the purge gas for purging the gas remaining in the reaction tube 210 when the substrate processing described later is performed. The second element-containing gas supply system 260 may further include the second inert gas supply system.

It is preferable that no obstruction structure obstructing the flow of the gas is provided among the nozzle 223, the nozzles 225 and the substrate S.

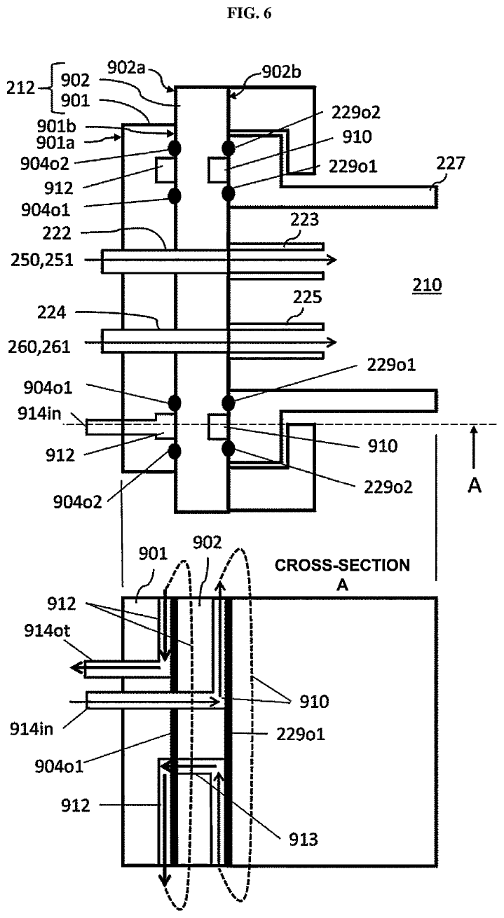

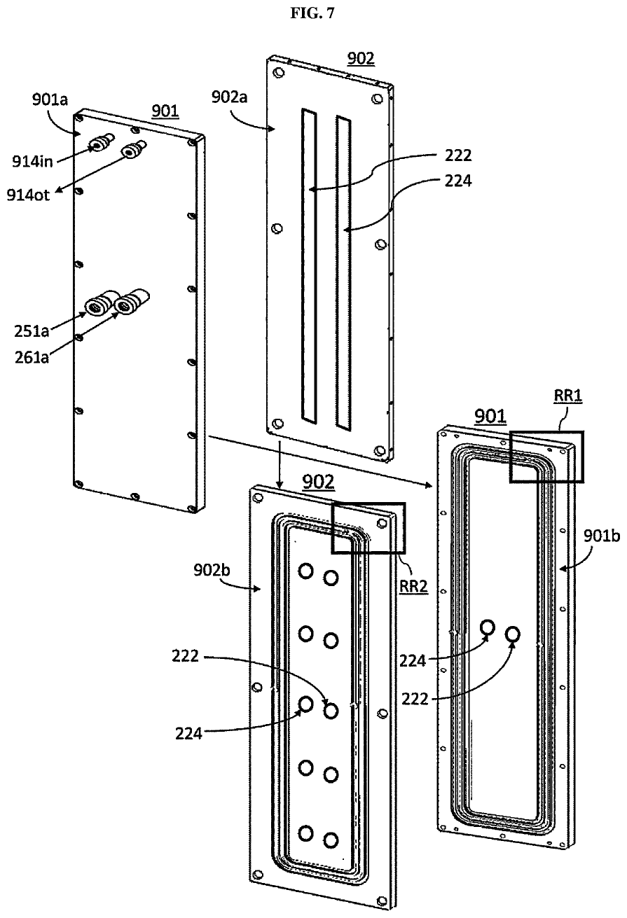

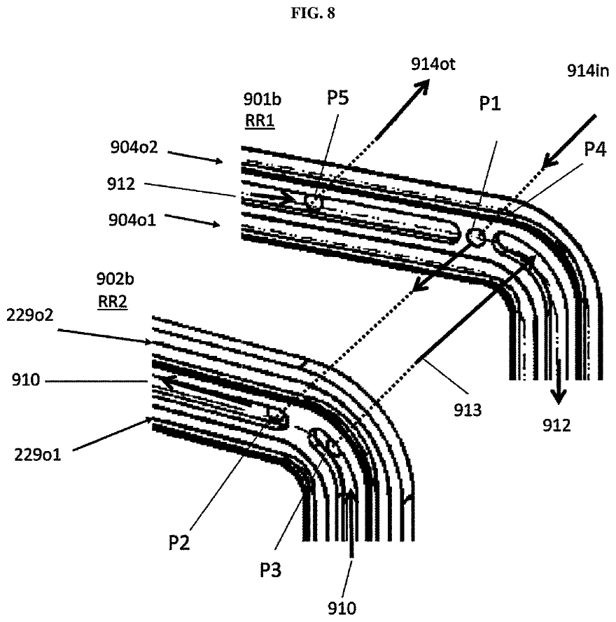

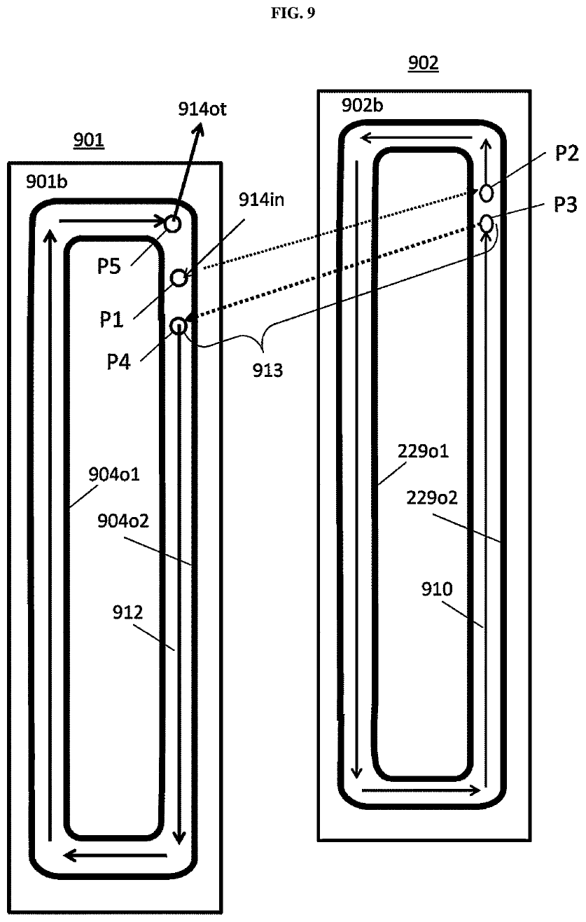

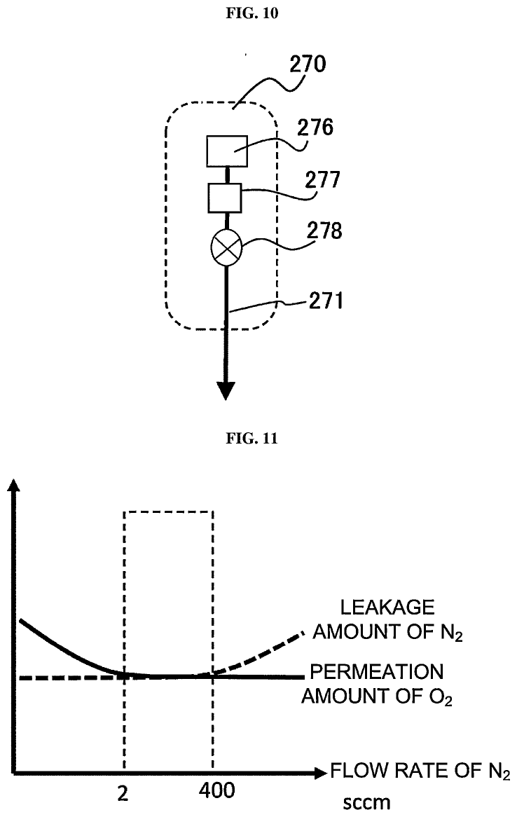

Subsequently, a configuration of the gas supply structure 212 will be described with reference to FIGS. 6 to 11. FIG. 6 is a diagram schematically illustrating a cross-section of the gas supply structure 212 according to the present embodiments. FIG. 7 is a diagram schematically illustrating a perspective view of front and back surfaces of a first structure (first component) 901 and a second structure (second component) 902 according to the present embodiments. FIG. 8 is a diagram schematically illustrating a partial perspective view of the front and back surfaces of the first structure 901 and the second structure 902 according to the present embodiments. FIG. 9 is a diagram schematically illustrating a first purge gas path 910 and a second purge gas path 912 according to the present embodiments. FIG. 10 is a diagram schematically illustrating a purge gas supply system 270 according to the present embodiments. FIG. 11 is a diagram schematically illustrating a permeation amount of oxygen (O₂) (that is, an amount of oxygen (O₂) permeated) according to present embodiments. Hereinafter, a technique capable of reducing the risk of oxygen (O₂) permeation at a connection structure of an opening of a vacuum vessel will be described using the gas supply structure 212 as an example configuration.

As shown in FIG. 6, the gas supply structure 212 and the housing 227 are separable from each other. When fixing the gas supply structure 212 and the housing 227 with each other, the gas supply structure 212 and the housing 227 are fixed via the O-ring such as the O-ring 22901 and the O-ring 229o2. In other words, the opening of the vacuum vessel (that is, the reaction tube 210) constituted by the housing 227 is connected to the gas supply structure 212. Therefore, there may be a high risk of oxygen (O₂) permeation at the connection structure between the opening of the vacuum vessel and the gas supply structure 212. In order to reduce the risk of oxygen (O₂) permeation, for example, the gas supply structure 212 may be configured as follows.

For example, the gas supply structure 212 is constituted by the first structure 901 and the second structure 902. As shown in FIG. 9, each of the first structure 901 and the second structure 902 is configured as a single plate such as a rectangular plate.

The first structure 901 includes a front surface 901a and a back surface 901b facing the front surface 901a. The second structure 902 includes a front surface 902a and a back surface 902b facing the front surface 902a. The back surface 901b and the front surface 902a are connected. The back surface 902b is connected to the housing 227 serving as a third structure.

As shown schematically in FIG. 6, the gas supply structure 212 is configured such that the gas supply pipe 251 connected to the first element-containing gas supply system 250 and the gas supply pipe 261 connected to the second element-containing gas supply system 260 are connected to the nozzles 223 and 225 via the distributors 222 and 224, respectively. Thereby, it is possible to supply the gas such as the source gas and the reactive gas into the reaction tube 210.

Between the back surface 901b and the front surface 902a, a first seal 904o1 is provided so as to surround the distributors 222 and 224. In other words, the first seal 904o1 is located between the back surface 901b of the first structure 901 and the front surface 902a of the second structure 902, and is provided with flow paths (that is, the distributors 222 and 224) of the process gases therein. In addition, on the back surface 901b, the second purge gas path (also referred to as a “second gas path”) 912 is provided along an outer periphery of the first seal 904o1, and is configured such that the purge gas flows inside the second purge gas path 912. In addition, between the back surface 901b and the front surface 902a, a third seal 904o2 is arranged along an outer periphery of the second purge gas path 912. The second purge gas path 912 is configured by blocking a recess provided on the back surface 901b of the first structure 901 with the front surface 902a of the second structure 902.

In addition, the second seal 229o1 is provided between the back surface 902b and the housing 227 so as to surround the distributors 222 and 224. The second seal 229o1 is located between the back surface 902b of the second structure 902 and the housing 227, and is provided with the flow paths (that is, the distributors 222 and 224) of the process gases therein. In addition, the first purge gas path (also referred to as a “first gas path”) 910 is provided along an outer periphery of the second seal 229o1 on the back surface 902b, and is configured such that the purge gas flows inside the first purge gas path 910. Further, between the back surface 902b and the housing 227, the fourth seal 229o2 is provided along an outer periphery of the first purge gas path 910. The first purge gas path 910 is configured by blocking a recess provided on the back surface 902b of the second structure 902 with the surface (side surface) of the housing 227.

Referring to a cross-section “A” shown in FIG. 6, a third purge gas path (also referred to as a “third gas path”) 913 configured to connect the first purge gas path 910 and the second purge gas path 912 is provided at the second structure 902. In addition, the first structure 901 is also provided with a purge gas supply port (that is, a supply port through which a second gas is supplied) 914in and a purge gas exhaust port (that is, an exhaust port through which the second gas is exhausted) 914ot. For example, in the present embodiments, the purge gas may also be referred to as a “second gas.” For example, the purge gas (inert gas) serving as the second gas is supplied to the first purge gas path 910 through the purge gas supply port 914in, and is exhausted from the second purge gas path 912 through the purge gas exhaust port 914ot. The purge gas supply port 914in and the purge gas exhaust port 914ot are disposed adjacent to each other. As described later in FIG. 10, the purge gas supply port 914in is connected to the purge gas supply system 270, and is configured such that purge gas (inert gas) (for example, nitrogen (N₂) gas) from an inert gas supply source 276 is supplied through the purge gas supply port 914in. The purge gas supply system 270 may also be referred to as a “second gas supplier”. The purge gas supplied through the purge gas supply port 914in then flows sequentially through the first purge gas path 910, the third purge gas path 913 and the second purge gas path 912, and then is discharged through the purge gas exhaust port 914ot.

In the present embodiments, a flow direction of the purge gas relative to a flow direction of the process gas serving as the first element-containing gas is configured to be different in the first purge gas path 910 and in the second purge gas path 912. In other words, referring to the cross-section “A” shown in FIG. 6, when the flow direction of the purge gas in the first purge gas path 910 is set to a first direction (for example, counterclockwise when viewed along the flow direction of the process gas), the flow direction of the purge gas in the second purge gas path 912 is set to a second direction different from the first direction (for example, clockwise when viewed along the flow direction of the process gas).

FIG. 7 is a diagram schematically illustrating a perspective view of the front surfaces 901a and 902a of the first structure 901 and the second structure 902 constituting the gas supply structure (gas supply assembly) 212 and a perspective view of the back surfaces 901b and 902b of the first structure 901 and the second structure 902. The purge gas supply port (second gas supply port) 914in and the purge gas exhaust port (second gas exhaust port) 914ot are arranged adjacent to each other on the front surface 901a of the first structure. In addition, gas supply ports 251a and 261a are also arranged on the front surface 901a of the first structure 901. The distributors 222 and 224 are provided on the front surface 902a and the back surfaces 901b and 902b. The process gas (such as the source gas (first element-containing gas) and the reactive gas (second element-containing gas) respectively supplied from the first element-containing gas supply system 250 and the second element-containing gas supply system 260) flows into each of the distributors 222 and 224 of the first structure 901 and the second structure 902 via the gas supply ports (first gas supply ports) 251a and 261a. Hereinafter, the first element-containing gas supply system 250 and the second element-containing gas supply system 260 may also be collectively or individually referred to as a “first gas supplier”.

FIG. 8 is a diagram schematically illustrating an enlarged perspective view of regions RR1 and RR2 shown in FIG. 7 along with a flow of the purge gas. As shown in FIG. 8, the back surface 901b is provided with a region where the first seal 904o1 is arranged and a region where the third seal 904o2 is arranged, and the second purge gas path 912 is provided between the region where the first seal 904o1 is arranged and the region where the third seal 904o2 is arranged. The back surface 902b is provided with a region where the second seal 229o1 is arranged and a region where the fourth seal 229o2 is arranged, and the first purge gas path 910 is provided between the region where the second seal 229o1 is arranged and the region where the fourth seal 229o2 is arranged.

The purge gas (second gas) from the purge gas supply port 914 in flows through an opening P1 of the first structure 901 to an opening P2 of the second structure 902, and then flows in the first purge gas path 910 along the outer periphery of the first seal 904o1 (toward the left in FIG. 8). Then, the purge gas travels almost a full circle along the outer periphery of the first seal, and reaches an opening P3 of the second structure 902 from below.

The purge gas supplied to the opening P3 then reaches a region P4 of the first structure 901 through the third purge gas path 913. In other words, the third purge gas path 913 is provided between the opening P3 and the region P4.

The purge gas supplied to the region P4 flows along the outer periphery of the second seal 229o1 (towards the lower left in FIG. 8) into the second purge gas path 912. Then, the purge gas travels almost a full circle along the outer periphery of the second seal 229o1, and reaches an opening P5 of the first structure 901 from the right. The purge gas supplied to the opening P5 is discharged through the purge gas exhaust port 914ot.

FIG. 9 is a diagram schematically illustrating an overall flow of the purge gas in the first purge gas path 910 and the second purge gas path 912. Since the path through which the purge gas flows was described with reference to in FIG. 8, redundant descriptions thereof will be omitted.

A flow path of the purge gas is from the second structure 902 (which is an inner plate) to the first structure 901 (which is an outer plate). When a temperature of the inner plate (that is, the second structure 902) is high, the risk of oxygen (O₂) permeation increases, but it is possible to flow the purge gas serving as a cooling gas through the inner plate (that is, the second structure 902). Therefore, by flowing the purge gas first through the inner plate (that is, the second structure 902) whose temperature is higher than that of the outer plate (that is, the first structure 901), it is possible to lower the temperature of the inner plate (that is, the second structure 902). Thereby, it is possible to reduce the risk of oxygen (O₂) permeation.

In order to minimize the number of regions where the purge gas does not flow, the purge gas supply port 914in and the purge gas exhaust port 914ot are arranged close to each other. As a result, the flow direction of the purge gas is reversed on the inner plate (that is, the second structure 902) and the outer plate (that is, the first structure 901). Since the flows of the purge gas are reversed as described above, it is possible to average out cooling temperatures of the structures of the inner plate (that is, the second structure 902) and the outer plate (that is, the first structure 901) caused by the purge gas.

As shown in FIG. 10, the inert gas supply source 276, a mass flow controller (MFC) 277 and a valve 278 serving as an opening/closing valve are sequentially installed at a gas supply pipe 271 in this order from an upstream side to a downstream side of the gas supply pipe 271. The inert gas (for example, the nitrogen (N₂) gas) serving as the purge gas is supplied from the inert gas supply source 276.

The purge gas supply system 270 is constituted mainly by the gas supply pipe 271, the inert gas supply source 276, the MFC 277 and the valve 278. The gas supply pipe 271 is connected to the purge gas supply port 914 in, and the inert gas supplied from the inert gas supply source 276 acts as the purge gas supplied to the first purge gas path 910 and the second purge gas path 912 when the substrate processing described later is performed.

From a result of each calibration curve in a graph shown in FIG. 11, when the permeation amount of oxygen (O₂) is about 0.02 sccm, by diluting the oxygen 100 times or more, it is possible to eliminate an influence of permeation into the process chamber 210. It is preferable that a flow rate of nitrogen (N₂) serving as the purge gas is set to be within a range from 2 sccm to 400 sccm. It can be seen that, when the flow rate of N₂ is less than 2 sccm, the risk of O₂ permeation (that is, the permeation amount of oxygen) cannot be reduced. On the other hand, when the flow rate of N₂ is more than 400 sccm, a pressure (inner pressure) of a nitrogen (N₂) flow path (such as the first purge gas path 910, the second purge gas path 912 and the third purge gas path 913) becomes high, and there is a high possibility that N₂ will leak (that is, a leakage amount of the nitrogen will increase) from the N₂ flow path to the outside. In addition, a large amount of N₂ will be consumed.

For example, in the present specification, a notation of a numerical range such as “from 2 sccm to 400 sccm” means that a lower limit and an upper limit are contained in the numerical range. Therefore, for example, a numerical range “from 2 sccm to 400 sccm” means a range equal to or higher than 2 sccm and equal to or less than 400 sccm. The same also applies to other numerical ranges described in the present specification.

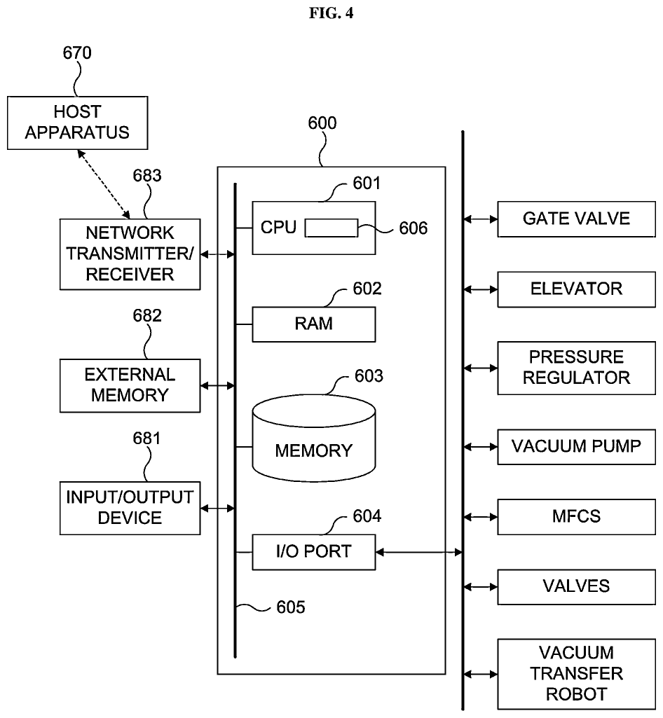

Subsequently, a controller 600 serving as a control structure (control apparatus) will be described with reference to FIG. 4. The substrate processing apparatus 100 includes the controller 600 configured to control operations of components constituting the substrate processing apparatus 100.

FIG. 4 is a diagram schematically illustrating a configuration of the controller 600. For example, the controller 600 is constituted by a computer including a CPU (Central Processing Unit) 601, a RAM (Random Access Memory) 602, a memory 603 serving as a memory structure and an I/O port (input/output port) 604. The RAM 602, the memory 603 and the I/O port 604 can exchange data with the CPU 601 via an internal bus 605. The transmission/reception of the data in the substrate processing apparatus 100 may be performed by an instruction from a transmission/reception instruction controller 606 which is one of functions of the CPU 601.

A network transmitter/receiver 683 connected to a host apparatus 670 via a network is provided at the controller 600. For example, the network transmitter/receiver 683 is capable of receiving data such as information regarding a processing history and a processing schedule for the substrate S stored in a pod (not shown) from the host apparatus 670.

For example, the memory 603 may be embodied by a component such as a flash memory and an HDD (Hard Disk Drive). For example, a control program for controlling the operations of the substrate processing apparatus 100 or a process recipe in which information such as process procedures and process conditions of the substrate processing is stored may be readably stored in the memory 603.

For example, the process recipe is obtained by combining steps (process procedures) of the substrate processing described later, and acts as a program that is executed by the controller 600 to obtain a predetermined result by performing the steps of the substrate processing described later. Hereinafter, the process recipe and the control program may be collectively or individually referred to simply as a “program.” Thus, in the present specification, the term “program” may refer to the process recipe alone, may refer to the control program alone, or may refer to both of the process recipe and the control program. The RAM 602 serves as a memory area (work area) in which the program or the data read by the CPU 601 is temporarily stored.

The I/O port 604 is electrically connected to the components of the substrate processing apparatus 100 described above. The CPU 601 is configured to read and execute the control program from the memory 603, and is configured to read the process recipe from the memory 603 in accordance with an instruction such as an operation command inputted from an input/output device 681. The CPU 601 is configured to be capable of controlling the substrate processing apparatus 100 in accordance with contents of the process recipe read from the input/output device 681.

The CPU 601 includes the transmission/reception instruction controller 606. For example, the controller 600 according to the present embodiments may be embodied by preparing an external memory 682 (for example, a magnetic disk such as a hard disk, an optical disk such as a DVD, a magneto-optical disk such as an MO, a semiconductor memory such as a USB memory) storing the program described above and by installing the program onto the computer by using the external memory 682. However, a method of providing the program to the computer is not limited to that using the external memory 682. For example, the program may be directly provided to the computer by a communication interface such as the Internet and a dedicated line instead of the external memory 682. Further, the memory 603 and the external memory 682 may be embodied by a non-transitory computer-readable recording medium. Hereinafter, the memory 603 and the external memory 682 may be collectively or individually referred to as a “recording medium”. Thus, in the present specification, the term “recording medium” may refer to the memory 603 alone, may refer to the external memory 682 alone, or may refer to both of the memory 603 and the external memory 682.

Hereinafter, as a part of a manufacturing process of a semiconductor device (that is, a method of manufacturing the semiconductor device or a substrate processing method), the substrate processing will be described by way of an example in which a film-forming process of forming a film on the substrate S is performed by using the substrate processing apparatus 100 described above. In the following description, the controller 600 controls the operations of the components constituting the substrate processing apparatus 100.

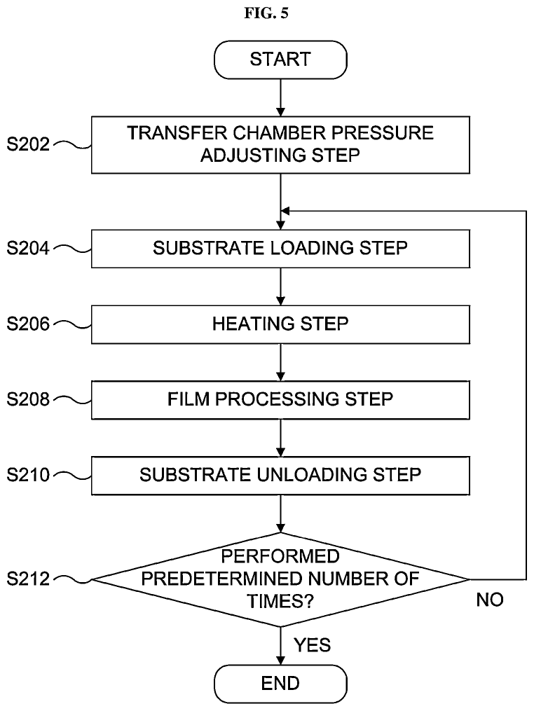

For example, the film-forming process of forming the film on the substrate S by alternately supplying the first element-containing gas and the second element-containing gas will be described with reference to FIG. 5.

### S202

A transfer chamber pressure adjusting step S202 will be described. In the present step, a pressure (inner pressure) of the transfer chamber 217 is set to the same level as that of a vacuum transfer chamber (not shown) provided adjacent to the transfer chamber 217. Specifically, by operating an exhauster (which is an exhaust system) (not shown) connected to the transfer chamber 217, an atmosphere (inner atmosphere) of the transfer chamber 217 is exhausted such that the inner pressure of the transfer chamber 217 reaches and is maintained at a vacuum level.

Further, a heater 228 may be operated in parallel with the step S202. Specifically, each of a heater 228a and a heater 228b may be operated. When the heater 228 is operated, the heater 228 is continuously operated at least until a film processing step S208 described later is completed.

### S204

Subsequently, a substrate loading step S204 will be described.

When the inner pressure of the transfer chamber 217 reaches the vacuum level, a transfer of the substrate S is started. When the substrate S reaches the vacuum transfer chamber (not shown), a gate valve (not shown) provided adjacent to a substrate loading/unloading port (not shown) is opened. Then, the substrate S is loaded (transferred) from the vacuum transfer chamber (not shown) adjacent to the transfer chamber 217 into the transfer chamber 217.

In the present step, the substrate support 300 stands by in the transfer chamber 217, and the substrate S is transferred to the substrate support 300. When a predetermined number of the substrates S are transferred to the substrate support 300, the vacuum transfer robot (not shown) is retracted, and the substrate support 300 is elevated by the vertical driving structure 400 to move the substrates S into the reaction tube 210.

When moving the substrate S into the reaction tube 210, the substrate S is position-determined such that a height of its surface is aligned with heights of the partition plate 226 and the partition plate 232.

### S206

Subsequently, a heating step S206 will be described. When the substrate S is loaded into the reaction tube 210, the inner pressure of the reaction tube 210 is controlled (or adjusted) to be a predetermined pressure, and a surface temperature of the substrate S is controlled to be a predetermined temperature by controlling the heater 211. The temperature (that is, the surface temperature) is a temperature within a high temperature range described later. For example, the substrate S is heated to the temperature within a range of 400° C. or higher and 800° C. or lower, preferably 500°° C. or higher and 700° C. or lower. For example, the pressure (that is, the inner pressure of the reaction tube 210) may be a pressure within a range from 50 Pa to 5,000 Pa. In the heating step S206, when the heater 228 is operated, the gas passing through an inner portion of the distributor 222 is controlled to be heated to a temperature in a low decomposition temperature range or an undecomposition temperature range which will be described later such that the gas is not re-liquefied.

In the present step, the MFC 277 and the valve 278 are controlled in accordance with the process recipe such that the purge gas from the inert gas supply source 276 is supplied through the gas supply pipe 271 toward the first purge gas path 910 and the second purge gas path 912. The purge gas is continuously supplied from the inert gas supply source 276 at least until the film processing step S208 described later is completed.

### S208

Subsequently, the film processing step S208 will be described. After the heating step S206, the film processing step S208 is performed. In the film processing step S208, in accordance with the process recipe, the first element-containing gas supply system 250 is controlled to supply the first element-containing gas into the reaction tube 210, and the exhauster (not shown) is controlled to exhaust the process gases such as the first element-containing gas from the reaction tube 210. Further, in the film processing step S208, the second element-containing gas supply system 260 is controlled such that the second element-containing gas exists in the process space simultaneously with the first element-containing gas so as to perform a CVD (chemical vapor deposition) process, or such that the first element-containing gas and the second element-containing gas are alternately supplied into the reaction tube 210 so as to perform an alternate supply process. Thereby, the film is formed. Further, when the second element-containing gas in a plasma state is to be used, the second element-containing gas may be converted into the plasma state by using a plasma generator (not shown).

The following method may be used as the alternate supply process serving as a specific example of a film processing method. For example, a first step of supplying the first element-containing gas into the reaction tube 210, a second step of supplying the second element-containing gas into the reaction tube 210 and a purge step of supplying nitrogen (N₂) gas serving as the inert gas into the reaction tube 210 and exhausting the inner atmosphere of the reaction tube 210 between the first step and the second step may be performed. That is, a desired film is formed by performing the alternate supply process in which a combination of the first step, the purge step and the second step is performed a plurality number of times.

When the gas is supplied, the flow of the gas is formed over the upstream side gas guide 214, a space on the substrate S and the downstream side gas guide 215. In the present step, since the gas is supplied to each of the substrates S without the pressure loss on each of the substrates S, it is possible to uniformly process the substrates S.

### S210

Subsequently, a substrate unloading step S210 will be described. In the substrate unloading step S210, the substrates S processed as described above are transferred (unloaded) out of the transfer chamber 217 in an order reverse to that of the substrate loading step S204 described above.

### S212

Subsequently, a determination step S212 will be described. In the present step, it is determined whether or not a processing described above (that is, the step S204 through S210) has been performed a predetermined number of times. When it is determined that the processing has not been performed the predetermined number of times, the substrate loading step S204 is performed again to process a subsequent substrate S to be processed. When it is determined that the processing has been performed the predetermined number of times, the substrate processing is terminated.

While the present embodiments are described by way of an example in which the flow of the gas in the horizontal direction is formed, the present embodiments are not limited thereto. For example, it would suffice if a main flow of the gas is formed generally in the horizontal direction. Further, a flow of the gas diffused in the vertical direction may be formed as long as it does not affect a uniform processing of the substrates S.

In addition, in the above, various expressions such as “the same,” “similar” and the like are used. However, it goes without saying that the expressions described above may mean “substantially the same.”

While the technique of the present disclosure is described in detail by way of the embodiments mentioned above, the technique of the present disclosure is not limited thereto. For example, the technique of the present disclosure may be modified in various ways without departing from the scope thereof.

For example, the embodiments mentioned above are described by way of an example in which, in the film-forming processing process performed by the substrate processing apparatus 100, the film is formed on the substrate S by using the first element-containing gas and the second element-containing gas. However, the technique of the present disclosure is not limited thereto. That is, as the process gases used in the film-forming process, other gases may be used to form different films. In addition, the technique of the present disclosure may also be applied to film-forming processes using three or more different process gases as long as the three or more different process gases are non-simultaneously supplied (that is, supplied in a non- overlapping manner).

For example, the embodiments mentioned above are described by way of an example in which the gas containing silicon and further containing a silicon-silicon bond (Si—Si bond) is used as the first element-containing gas. However, the technique of the present disclosure is not limited thereto. As the first element-containing gas, for example, a gas such as tetrachloro dimethyl disilane ((CH₃)₂Si₂Cl₄, abbreviated as TCDMDS), hexachlorodisilane (Si₂Cl₆, abbreviated as HCDS) and dichloro tetramethyl disilane ((CH₃)₄Si₂Cl₂, abbreviated as DCTMDS) may be used. The TCDMDS contains a Si—Si bond, and further contains a chloro group and an alkylene group. Further, the DCTMDS contains a Si—Si bond, and further contains a chloro group and an alkylene group. As the first element, for example, an element such as titanium (Ti), silicon (Si), zirconium (Zr) and hafnium (Hf) may be used.

The second element-containing gas contains the second element different from the first element. As the second element, for example, an element such as oxygen (O), nitrogen (N) and carbon (C) may be used. In the embodiments mentioned above, as the second element-containing gas, for example, a nitrogen-containing gas may be used. Specifically, as the second element-containing gas, for example, a hydrogen nitride-based gas containing a nitrogen-hydrogen bond (N—H bond) such as ammonia (NH₃), diazene (N₂H₂) gas, hydrazine (N₂H₄) gas and N₃H₈ gas may be used.

For example, the embodiments mentioned above are described by way of an example in which a batch type substrate processing apparatus capable of simultaneously processing a plurality of substrates is used to form the film. However, the technique of the present disclosure is not limited thereto. For example, the technique of the present disclosure may be preferably applied when a single wafer type substrate processing apparatus capable of processing one or several substrates at once is used to form the film. For example, the embodiments mentioned above are described by way of an example in which a substrate processing apparatus including a hot wall type process furnace is used to form the film. However, the technique of the present disclosure is not limited thereto. For example, the technique of the present disclosure may be preferably applied when a substrate processing apparatus including a cold wall type process furnace is used to form the film.

For example, the embodiments mentioned above are described by way of an example in which the film-forming process is performed by the substrate processing apparatus. However, the technique of the present disclosure is not limited thereto. That is, the technique of the present disclosure can be applied not only to the film-forming process of forming the film exemplified in the embodiments mentioned above but also to other film-forming processes of forming other films. Further, one or more constituents of the embodiments mentioned above may be substituted with one or more constituents of other embodiments, or may be added to other embodiments. Further, a part of one or more constituents of the embodiments mentioned above may be omitted, or substituted with or added by other constituents.

As described above, according to some embodiments of the present disclosure, it is possible to reduce the risk of oxygen (O₂) permeation.

What is claimed is:

1. A substrate processing apparatus comprising:
a first gas supplier configured to supply a first gas;
a first structure configured to allow the first gas to pass therethrough from the first gas supplier;
a second structure configured to allow the first gas to pass therethrough from the first structure;
a third structure configured to allow the first gas to pass therethrough from the second structure;
a process chamber to which the first gas is supplied from the third structure;
a first seal provided between the first structure and the second structure;
a second seal provided between the second structure and the third structure;
a second gas supplier configured to supply a second gas;
a first gas path arranged along the second seal and configured to allow the second gas to pass therethrough; and
a second gas path arranged along the first seal and configured to allow the second gas to pass therethrough.

2. The substrate processing apparatus of claim 1, further comprising:
a third gas path arranged between the first gas path and the second gas path and configured to allow the second gas to pass therethrough.

3. The substrate processing apparatus of claim 1, wherein the first gas path is provided between the second structure and the third structure.

4. The substrate processing apparatus of claim 1, wherein the second gas path is provided between the first structure and the second structure.

5. The substrate processing apparatus of claim 1, wherein a flow direction of the second gas flowing through the first gas path is different from a flow direction of the second gas flowing through the second gas path.

6. The substrate processing apparatus of claim 1, wherein the first gas supplier is connected to the first structure.

7. The substrate processing apparatus of claim 1, wherein the second gas supplier is connected to the first structure.

8. The substrate processing apparatus of claim 1, further comprising:
an exhauster through which the second gas is exhausted.

9. The substrate processing apparatus of claim 8, wherein the exhauster is connected to the first structure.

10. The substrate processing apparatus of claim 8, wherein the second gas supplier and the exhauster are connected to the first structure.

11. The substrate processing apparatus of claim 10, wherein a supply port through which the second gas is supplied and an exhaust port through which the second gas is exhausted are provided adjacent to each other.

12. The substrate processing apparatus of claim 11, wherein the second gas path is provided along an outer periphery of the first seal.

13. The substrate processing apparatus of claim 1, wherein the first gas path is provided along an outer periphery of the second seal.

14. The substrate processing apparatus of claim 1, wherein the second gas path is provided along an outer periphery of the first seal.

15. The substrate processing apparatus of claim 1, wherein the first gas comprises a process gas.

16. The substrate processing apparatus of claim 1, wherein the second gas comprises a purge gas.

17. A gas supply assembly comprising:
a first gas supplier configured to supply a first gas;
a first structure configured to allow the first gas to pass therethrough from the first gas supplier;
a second structure configured to allow the first gas to pass therethrough from the first structure;
a third structure configured to allow the first gas to pass therethrough from the second structure;
a first seal provided between the first structure and the second structure;
a second seal provided between the second structure and the third structure;
a second gas supplier configured to supply a second gas;
a first gas path arranged along the second seal and configured to allow the second gas to pass therethrough; and
a second gas path arranged along the first seal and configured to allow the second gas to pass therethrough.

18. A substrate processing method comprising:
(a) loading a substrate into a process chamber of a substrate processing apparatus, wherein the substrate processing apparatus comprises:
a first gas supplier configured to supply a first gas;
a first structure configured to allow the first gas to pass therethrough from the first gas supplier;
a second structure configured to allow the first gas to pass therethrough from the first structure;
a third structure configured to allow the first gas to pass therethrough from the second structure;
a first seal provided between the first structure and the second structure;
a second seal provided between the second structure and the third structure;
a second gas supplier configured to supply a second gas;
a first gas path arranged along the second seal and configured to allow the second gas to pass therethrough; and
a second gas path arranged along the first seal and configured to allow the second gas to pass therethrough; and
(b) processing the substrate by supplying the first gas.

19. A method of manufacturing a semiconductor device, comprising:
the substrate processing method of claim 18.

20. A non-transitory computer-readable recording medium storing a program that causes a substrate processing apparatus, by a computer, to perform a process comprising the substrate processing method of claim 18.
